(19) United States
(12) Patent Application Publication
(10) Pub. No.: US 2024/0393889 A1
(43) Pub. Date: Nov. 28, 2024

(54) INPUT KEY ASSEMBLY AND INPUT DEVICE

(71) Applicant: Razer (ASIA-PACIFIC) PTE LTD., Singapore (SG)

(72) Inventor: Kok Kiong LOW, Singapore (SG)

(73) Assignee: Razer (ASIA-PACIFIC) PTE LTD., Singapore (SG)

(21) Appl. No.: 18/697,022

(22) PCT Filed: Dec. 10, 2021
(86) PCT No.: PCT/SG2021/050782

§ 371 Date: Mar. 29, 2024

(51) Int. Cl. G06F 3/02; H01H 13/26; H01H 13/78; H03K 17/969

(52) U.S. Cl. CPC G06F 3/0202; H01H 13/26; H01H 13/78; H03K 17/969; H01H 2223/038; H01H 2227/022; H01H 2235/008; H01H 2235/014; H01H 2237/008

(57) ABSTRACT

An input key assembly including: a keycap; a substrate; an elastic deformable shell-like structure disposed between the substrate and the keycap; and an optical sensing arrangement disposed on the substrate to transmit a light beam and sense an interruption to the light beam. The elastic deformable shell-like structure includes a peripheral base portion in abutment with the substrate; an apex portion in abutment with the keycap; and a plunger-like element extending away from underneath the apex portion, wherein a free-end of the plunger-like element is opaque. The elastic deformable shell-like structure and the optical sensing arrangement are arranged in a manner such that the free-end of the plunger-like element interrupts the light beam when the keycap is depressed to deform the elastic deformable shell-like structure for collapsing the apex portion relative to the peripheral base portion to move the plunger-like element along a longitudinal axis of the plunger-like element.

### TECHNICAL FIELD

Various embodiments generally relate to an input key assembly and an input device including the input key assembly.

### BACKGROUND

Keycaps of a keyboard are typically built around the base size of 1 u, which is the size of one typical alphanumeric key. Accordingly, highly sought after key switches, such as optical switches, are also configured to be within the base size of 1 u for fitting to the keyboard. While some of these optical key switches may be configured to have a low profile or an ultra-low profile, these optical key switches merely have a reduced height while maintaining the same footprint. Hence, only keys with a minimum size of 1 u can be fitted with these optical key switches. For built-in keyboard in a laptop or a notebook, due to space or size constraints, some of the keys may generally be configured to be smaller than the base size of 1 u. In such cases, these smaller keys cannot be fitted with such highly sought after conventional optical switches.

Accordingly, there is a need for an improved input key assembly to address some of the above issues.

### SUMMARY

According to various embodiments, there is provided an input key assembly including: a keycap; a substrate; an elastic deformable shell-like structure disposed between the substrate and the keycap; and an optical sensing arrangement disposed on the substrate to transmit a light beam and sense an interruption to the light beam. The elastic deformable shell-like structure includes a peripheral base portion in abutment with the substrate; an apex portion in abutment with the keycap, wherein the peripheral base portion tapers towards the apex portion; and a plunger-like element extending from underneath the apex portion and away from the apex portion, wherein a free-end of the plunger-like element is opaque. The elastic deformable shell-like structure and the optical sensing arrangement are arranged in a manner so as to interrupt the light beam with the free-end of the plunger-like element when the keycap is depressed to deform the elastic deformable shell-like structure for collapsing the apex portion relative to the peripheral base portion to move the plunger-like element along a longitudinal axis of the plunger-like element.

According to various embodiments, there is provided an input device including a plurality of input keys. At least one of the plurality of input keys includes an input key assembly including: a keycap; a substrate; an elastic deformable shell-like structure disposed between the substrate and the keycap; and an optical sensing arrangement disposed on the substrate to transmit a light beam and sense an interruption to the light beam. The elastic deformable shell-like structure of the input key assembly includes a peripheral base portion in abutment with the substrate; an apex portion in abutment with the keycap, wherein the peripheral base portion tapers towards the apex portion; and a plunger-like element extending from underneath the apex portion and away from the apex portion, wherein a free-end of the plunger-like element is opaque. The elastic deformable shell-like structure and the optical sensing arrangement of the input key assembly are arranged in a manner so as to interrupt the light beam with the free-end of the plunger-like element when the keycap is depressed to deform the elastic deformable shell-like structure for collapsing the apex portion relative to the peripheral base portion to move the plunger-like element along a longitudinal axis of the plunger-like element.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments are described with reference to the following drawings, in which:

FIG. 1A shows a schematic cross-sectional view of an input key assembly according to various embodiments;

FIG. 1B shows a schematic cross-sectional view of the input key assembly of FIG. 1A being actuated or depressed according to various embodiments;

FIG. 2 shows a side view of an input key assembly according to various embodiments; and

FIG. 3 shows an input device according to various embodiments.

### DETAILED DESCRIPTION

Embodiments described below in the context of the apparatus are analogously valid for the respective methods, and vice versa. Furthermore, it will be understood that the embodiments described below may be combined, for example, a part of one embodiment may be combined with a part of another embodiment.

It should be understood that the terms “on”, “over”, “top”, “bottom”, “down”, “side”, “back”, “left”, “right”, “front”, “lateral”, “side”, “up”, “down” etc., when used in the following description are used for convenience and to aid understanding of relative positions or directions, and not intended to limit the orientation of any device, or structure or any part of any device or structure. In addition, the singular terms “a”, “an”, and “the” include plural references unless context clearly indicates otherwise. Similarly, the word “or” is intended to include “and” unless the context clearly indicates otherwise.

Various embodiments generally relate to an input key assembly and an input device including the input key assembly. According to various embodiments, the input key assembly may include a keycap and various elements of a switch arrangement underneath the keycap. According to various embodiments, the switch arrangement of the input key assembly may include a collapsible component and an optical sensing arrangement configured to interact with each other in a manner so as to be capable of achieving optical detection when the key is actuated or depressed. According to various embodiments, the collapsible component may include a modified rubber dome (or a modified elastomeric dome) configured to interact with the optical sensing arrangement. The conventional rubber dome (or conventional elastomeric dome) is commonly found in dome-switch keyboard or scissor-switch keyboard. However, in various embodiments, the modified rubber dome may differ from the conventional rubber dome in that the modified rubber dome may specifically be configured to interact with the optical sensing arrangement so as to optically detect whether the key is actuated or depressed. According to various embodiments, the optical sensing arrangement may include a set of transmitter (e.g. optical transmitter, light emitting diode (LED) transmitter, laser diode transmitter, or light transmitter) and receiver (e.g. optical receiver, light receiver, light sensor, photodetector, or photoelectric sensor), or a set of transceiver (e.g. optical transceiver, laser transceiver, light emitting diode (LED) transceiver, or light transceiver) and a reflector. Accordingly, in various embodiments, the modified rubber dome may be configured to interrupt a light beam generated by the optical sensing arrangement when the key is actuated or depressed such that the optical sensing arrangement may detect the interruption to the light beam as a measure of detecting the key is being actuated or depressed.

According to various embodiments, the input key assembly may further include a substrate. According to various embodiments, the collapsible component may be disposed between the keycap and the substrate. According to various embodiments, the substrate may include a circuit board or a printed circuit board. According to various embodiments, the collapsible component may be connected to the keycap, and may be elastically deformed from a neutral state to an actuated state when the keycap is actuated or depressed. In the actuated state, the collapsible component may be collapsed towards the substrate. According to various embodiments, the optical sensing arrangement may be disposed on the substrate. According to various embodiment, the collapsible component may include an opaque tip which may interrupt the light beam generated by the optical sensing arrangement when the collapsible component is collapsed towards the substrate.

According to various embodiments, the substrate may include a through-hole. According to various embodiments, when the keycap is depressed and the collapsible component is collapsed towards the substrate, the opaque tip of the collapsible component may be inserted into the through-hole to interrupt the light beam generated by the optical sensing arrangement.

According to various embodiments, the input key assembly may further include a scissors mechanism. According to various embodiments, the scissors mechanism may be between the keycap and the substrate. Hence, when the keycap is actuated or depressed, the scissors mechanism may also collapse towards the substrate.

According to various embodiments, an input device may include a plurality of input keys. According to various embodiments, at least one of the input keys may include the input key assembly of the various embodiments. According to various embodiments, the input device may include a first set of input keys using conventional key switch technology, such as conventional optical switch, conventional mechanical switch, conventional dome-switch, conventional scissor switch, etc., and a second set of input keys using the input key assembly of the various embodiments. According to various embodiments, the arrow keys of the input device may be using the input key assembly of the various embodiments. Accordingly, each of the arrow key of the input device may include the input key assembly of the various embodiments.

The following examples pertain to various embodiments.

Example 1 is an input key assembly including:
a keycap;
a substrate;
an elastic deformable shell-like structure disposed between the substrate and the keycap, wherein the elastic deformable shell-like structure includes
   a peripheral base portion in abutment with the substrate,
   an apex portion in abutment with the keycap, wherein the peripheral base portion tapers towards the apex portion, and
   a plunger-like element extending from underneath the apex portion and away from the apex portion, wherein a free-end of the plunger-like element is opaque; and
an optical sensing arrangement disposed on the substrate to transmit a light beam and sense an interruption to the light beam,
wherein the elastic deformable shell-like structure and the optical sensing arrangement are arranged in a manner so as to interrupt the light beam with the free-end of the plunger-like element when the keycap is depressed to deform the elastic deformable shell-like structure for collapsing the apex portion relative to the peripheral base portion to move the plunger-like element along a longitudinal axis of the plunger-like element.

In Example 2, the subject matter of Example 1 may optionally include that the substrate may include
a first surface,
a second surface, wherein the first surface and the second surface are opposite surfaces of the substrate, and
a through-hole extending between the first surface and the second surface,
wherein the peripheral base portion of the elastic deformable shell-like structure is in abutment with the first surface of the substrate and the plunger-like element of the elastic deformable shell-like structure is aligned with the through-hole such that the free-end of the plunger-like element is retractably insertable through the through-hole along the longitudinal axis of the plunger-like element when the keycap is depressed.

In Example 3, the subject matter of Example 2 may optionally include that the optical sensing arrangement may be disposed on the second surface of the substrate in a manner so as to transmit the light beam in a direction parallel to the second surface and across the through-hole.

In Example 4, the subject matter of any one of Examples 1 to 3 may optionally include that the optical sensing arrangement may include a transmitter and a receiver, or a transceiver and a reflector.

In Example 5, the subject matter of any one of Examples 1 to 4 may optionally include a scissor mechanism to guide a relative movement between the keycap and the substrate in a direction parallel to the longitudinal axis of the plunger-like element.

In Example 6, the subject matter of any one of Examples 1 to 5 may optionally include that the elastic deformable shell-like structure may include an inverted-bowl-like shape, a dome-like shape, a cone-like shape, a frustoconical-like shape, or a bell-like shape.

In Example 7, the subject matter of any one of Examples 1 to 6 may optionally include that the peripheral base portion and the apex portion of the elastic deformable shell-like structure may be transparent or translucent.

Example 8 is an input device including:
a plurality of input keys,
wherein at least one of the input keys includes
   an input key assembly including
      a keycap,
      a substrate,
      an elastic deformable shell-like structure disposed between the substrate and the keycap, wherein the elastic deformable shell-like structure includes
         a peripheral base portion in abutment with the substrate,
         an apex portion in abutment with the keycap, wherein the peripheral base portion tapers towards the apex portion, and
         a plunger-like element extending from underneath the apex portion and away from the apex portion, wherein a free-end of the plunger-like element is opaque, and
      an optical sensing arrangement disposed on the substrate to transmit a light beam and sense an interruption to the light beam,
      wherein the elastic deformable shell-like structure and the optical sensing arrangement are arranged in a manner so as to interrupt the light beam with the free-end of the plunger-like element when the keycap is depressed to deform the elastic deformable shell-like structure for collapsing the apex portion relative to the peripheral base portion to move the plunger-like element along a longitudinal axis of the plunger-like element.

In Example 9, the subject matter of Example 8 may optionally include that the substrate of the input key assembly includes
a first surface,
a second surface, wherein the first surface and the second surface are opposite surfaces of the substrate, and
a through-hole extending between the first surface and the second surface,
wherein the peripheral base portion of the elastic deformable shell-like structure is in abutment with the first surface of the substrate and the plunger-like element of the elastic deformable shell-like structure is aligned with the through-hole such that the free-end of the plunger-like element is retractably insertable through the through-hole along the longitudinal axis of the plunger-like element when the keycap is depressed.

In Example 10, the subject matter of Example 9 may optionally include that the optical sensing arrangement of the input key assembly may be disposed on the second surface of the substrate in a manner so as to transmit the light beam in a direction parallel to the second surface and across the through-hole.

In Example 11, the subject matter of any one of Examples 8 to 10 may optionally include that the optical sensing arrangement of the input key assembly may include a transmitter and a receiver, or a transceiver and a reflector.

In Example 12, the subject matter of any one of Examples 8 to 11 may optionally include a scissor mechanism to guide the relative movement between the keycap and the substrate in a direction parallel to the longitudinal axis of the plunger-like element.

In Example 13, the subject matter of any one of Examples 8 to 12 may optionally include that the elastic deformable shell-like structure of the input key assembly may include an inverted-bowl-like shape, a dome-like shape, a cone-like shape, a frustoconical-like shape, or a bell-like shape.

In Example 14, the subject matter of any one of Examples 8 to 13 may optionally include that the peripheral base portion and the apex portion of the elastic deformable shell-like structure of the input key assembly may be transparent or translucent.

In Example 15, the subject matter of any one of Examples 8 to 14 may optionally include that the plurality of keys includes arrow keys, wherein at least one of the arrow keys includes the input key assembly.

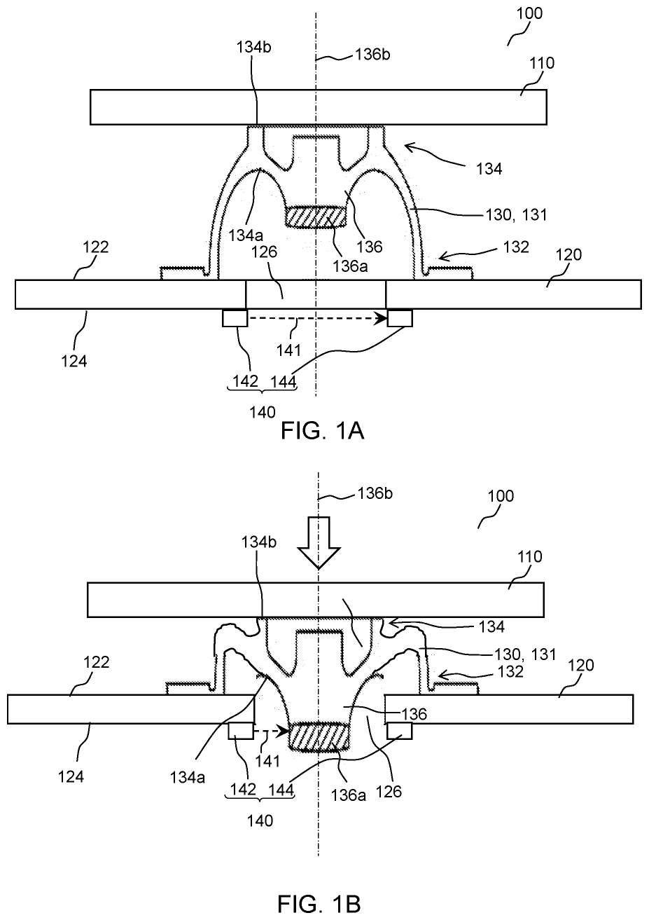

FIG. 1A shows a schematic cross-sectional view of an input key assembly 100 according to various embodiments. FIG. 1B shows a schematic cross-sectional view of the input key assembly 100 of FIG. 1A being actuated or depressed according to various embodiments. According to various embodiments, the input key assembly 100 may include a keycap 110. The keycap 110 may be a cover for each key of an input device. Accordingly, the keycap 110 may be the part of the key of the input device which is pressed or pushed by a user for actuating or depressing the key. According to various embodiments, the input key assembly 100 may include a substrate 120. According to various embodiments, the substrate 120 may include a circuit board or a printed circuit board.

According to various embodiments, the input key assembly 100 may include a collapsible component 130 disposed between the keycap 110 and the substrate 120. According to various embodiments, when the keycap 110 is being actuated or depressed relative to the substrate 120, the collapsible component 130 may be collapsed such that the keycap 110 may move towards the substrate 120. According to various embodiments, the collapsible component 130 may be an elastic deformable shell-like structure 131. Accordingly, the elastic deformable shell-like structure 131 may be disposed between the keycap 110 and the substrate 120. Hence, when the keycap 110 is being actuated or depressed relative to the substrate 120, the elastic deformable shell-like structure 131 may deform elastically and collapse such that the keycap 110 may move towards the substrate 120. According to various embodiments, the elastic deformable shell-like structure 131 may be shaped to resemble a covering that is generally concave and/or hollow. According to various embodiments, the clastic deformable shell-like structure 131 may include a hollow dome-like shape, a hollow cone-like shape, a hollow frustoconical-like shape, a hollow inverted-bowl-like shape, a hollow bell-like shape or any other suitable shape resembling a rubber dome (or elastomeric dome) for a dome-switch keyboard or scissor-switch keyboard. According to various embodiments, the elastic deformable shell-like structure 131 may include a miniature gazebo-like structure having a plurality of legs and a roof.

According to various embodiments, the elastic deformable shell-like structure 131 may include a peripheral base portion 132. According to various embodiments, for example, the peripheral base portion 132 may be a base edge portion of the hollow dome-like shape, a base edge portion of the hollow cone-like shape, a base edge portion of the hollow frustoconical-like shape, a rim portion of the hollow inverted-bowl-like shape, a mouth portion of the hollow bell-like shape, or feet portions of the legs of the miniature gazebo-like structure.

According to various embodiments, the peripheral base portion 132 of the clastic deformable shell-like structure 131 may be in abutment with the substrate 120. Accordingly, the peripheral base portion 132 of the elastic deformable shell-like structure 131 may be touching or joining the substrate 120. According to various embodiments, the peripheral base portion 132 of the elastic deformable shell-like structure 131 may be placed or rested or seated or laid on the substrate 120. According to various embodiments, the peripheral base portion 132 of the elastic deformable shell-like structure 131 may be attached or coupled or fixed or bonded or fasten to the substrate 120.

According to various embodiments, the elastic deformable shell-like structure 131 may include an apex portion 134. According to various embodiments, for example, the apex portion 134 may be a highest portion of the hollow dome-like shape, a top portion of the hollow cone-like shape, a top portion of the hollow frustoconical-like shape, a portion of the hollow inverted-bowl-like shape opposite the rim portion, a crown portion of the hollow bell-like shape, or the roof of the miniature gazebo-like structure.

According to various embodiments, the apex portion 134 of the clastic deformable shell-like structure 131 may be in abutment with the keycap 110. Accordingly, the keycap 110 may be touching or joining the apex portion 134 of the elastic deformable shell-like structure 131. According to various embodiments, the keycap 110 may be placed or rested or seated or laid on the apex portion 134 of the elastic deformable shell-like structure 131. According to various embodiments, the keycap 110 may be attached or coupled or fixed or bonded or fasten to the apex portion 134 of the elastic deformable shell-like structure 131. According to various embodiments, when the keycap 110 is being actuated or depressed relative to the substrate 120, the apex portion 134 of the elastic deformable shell-like structure 131 may deform elastically and collapse relative to the peripheral base portion 132 of the elastic deformable shell-like structure 131 such that the keycap 110 may move towards the substrate 120.

According to various embodiments, the peripheral base portion 132 of the elastic deformable shell-like structure 131 may taper towards the apex portion 134 of the clastic deformable shell-like structure 131. Accordingly, a width or diameter of the elastic deformable shell-like structure 131 may gradually become smaller or reduce from the peripheral base portion 132 of the elastic deformable shell-like structure 131 to the apex portion 134 of the elastic deformable shell-like structure 131. Hence, the width or the diameter of the elastic deformable shell-like structure 131 at the peripheral base portion 132 may be larger than the width or the diameter of the elastic deformable shell-like structure 131 at the apex portion 134. Thus, the peripheral base portion 132 of the elastic deformable shell-like structure 131 may extend downwards and outwards from the apex portion 134 of the elastic deformable shell-like structure 131.

According to various embodiments, the elastic deformable shell-like structure 131 may include a plunger-like element 136. According to various embodiments, the plunger-like element 136 may extend from underneath the apex portion 134 and away from the apex portion 134. Accordingly, the plunger-like element 136 may be extending from an underneath surface 134a of the apex portion 134. The underneath surface 134a may be opposite an exterior surface 134b (or outward facing surface) of the apex portion 134. The exterior surface 134b of the apex portion 134 may be in abutment with the keycap 110. According to various embodiments, the underneath surface 134a of the apex portion 134 may be directed in a direction along an axis of symmetry of the elastic deformable shell-like structure 131 from the apex portion 134 towards the peripheral base portion 132. Hence, the plunger-like element 136 may be extending from the underneath surface 134a of the apex portion 134, within an inner space defined by the elastic deformable shell-like structure 131, and away from the apex portion 134. According to various embodiments, the plunger-like element 136 may be aligned with the axis of symmetry of the elastic deformable shell-like structure 131.

According to various embodiments, a free-end 136a of the plunger-like element 136 of the elastic deformable shell-like structure 131 may be opaque. According to various embodiments, the free-end 136a of the plunger-like element 136 may be an end of the plunger-like element 136 distal from the apex portion 134 of the elastic deformable shell-like structure 131. Hence, the free-end 136a of the plunger-like element 136 may be an end of the plunger-like element 136 opposite a connection between the plunger-like element 136 and the apex portion 134. Thus, the free-end 136a of the plunger-like element 136 may be a portion of the plunger-like element 136 farthest from the apex portion 134. According to various embodiments, the free-end 136a of the plunger-like element 136 may be impenetrable to light. Accordingly, the free-end 136a of the plunger-like element 136 may block light or may not allow light to pass through. According to various embodiments, the free-end 136a of the plunger-like element 136 may be made of opaque material, or may be coated with opaque material, or may be coloured with opaque colours.

According to various embodiments, the input key assembly 100 may include an optical sensing arrangement 140. According to various embodiments, the optical sensing arrangement 140 may be disposed on the substrate 120. According to various embodiments, the optical sensing arrangement 140 may be mounted, or coupled, or attached, or fixed, or bonded to the substrate 120. According to various embodiments, the optical sensing arrangement 140 may be configured to generate and transmit a light beam 141 and configured to sense or detect an interruption to the light beam 141. According to various embodiments, the optical sensing arrangement 140 may include a light transmitting module and a light sensing module. The light transmitting module may be configured to generate and transmit the light beam 141, and the light sensing module may be configured to sense or detect the light beam 141. Accordingly, the light sensing module may also sense or detect a break or disruption of the light beam 141 when the light beam 141 is interrupted. According to various embodiments, the interruption to the light beam 141 may occur when the light beam 141 transmitted by the light transmitting module is being blocked by an opaque object such that the light beam 141 fails to reach the light sensing module.

According to various embodiments, the optical sensing arrangement 140 may include a set of a transmitter and a receiver. The transmitter may serve as the light emitting module for generating and transmitting the light beam 141 and the receiver may serve as the light sensing module for sensing and detecting an interruption to the light beam 141. The transmitter and the receiver may be two separate and independent components. The transmitter may include, but not limited to, an optical transmitter, a light emitting diode (LED) transmitter, a laser diode transmitter, or a light transmitter. The receiver may include, but not limited to, an optical receiver, a light receiver, a light sensor, a photodetector, or a photoelectric sensor. Accordingly, the transmitter and the receiver may be arranged in a manner such that the transmitter may project the light beam 141 to the receiver. Hence, the transmitter and the receiver may be disposed in an opposing manner such that the transmitter is directed towards the receiver for projecting the light beam 141 to the receiver. For example, as shown in FIG. 1A and FIG. 1B, a first component 142 of the optical sensing arrangement 140 may be the transmitter and a second component 144 of the optical sensing arrangement 140 may be the receiver.

According to various embodiments, the optical sensing arrangement 140 may include a set of a transceiver and a reflector. The transceiver may serve as both the light emitting module and the light sensing module. The transceiver may include, but not limited to, an optical transceiver, a laser transceiver, a light emitting diode (LED) transceiver, or a light transceiver. The transceiver may be configured to project the light beam 141 to the reflector and configured to detect and sense a reflected light beam from the reflector. Accordingly, the transceiver and the reflector may be arranged in a manner such that the transceiver may project the light beam 141 to the reflector and receive the reflected light beam from the reflector. Hence, the transceiver and the reflector may be disposed in an opposing manner such that the transceiver may be directed towards the reflector for projecting the light beam 141 to the reflector and receive the reflected light beam from the reflector. For example, as shown in FIG. 1A and FIG. 1B, the first component 142 of the optical sensing arrangement 140 may be the transceiver and the second component 144 of the optical sensing arrangement 140 may be the reflector.

According to various embodiments, the elastic deformable shell-like structure 131 and the optical sensing arrangement 140 may be arranged in a manner such that the free-end 136a of the plunger-like element 136 may interrupt the light beam 141 of the optical sensing arrangement 140 when the elastic deformable shell-like structure 131 is collapsed as the keycap 110 is being actuated or depressed. According to various embodiments, when the keycap 110 is being actuated or depressed to elastically deform the elastic deformable shell-like structure 131 for collapsing the apex portion 134 relative to the peripheral base portion 132, the plunger-like element 136 may be moved along a longitudinal axis 136b of the plunger-like element 136 so as to interrupt the light beam 141 with the free-end 136a of the plunger-like element 136. Accordingly, the elastic deformable shell-like structure 131 and the optical sensing arrangement 140 may be arranged in a manner whereby the longitudinal axis 136b of the plunger-like element 136 of the elastic deformable shell-like structure 131 may intersect the light beam 141 of the optical sensing arrangement 140 such that moving the plunger-like element 136 of the elastic deformable shell-like structure 131 along its longitudinal axis towards the light beam 141 of the optical sensing arrangement 140 as the apex portion 134 collapses relative to the peripheral base portion 132 may cause the free-end 136a of the plunger-like element 136 to interrupt the light beam 141 of the optical sensing arrangement 140.

According to various embodiments, the plunger-like element 136 of the elastic deformable shell-like structure 131 may be oriented with the longitudinal axis 136b of the plunger-like element 136 of the elastic deformable shell-like structure 131 substantially perpendicular to the light beam 141 of the optical sensing arrangement 140. Accordingly, moving the plunger-like element 136 of the elastic deformable shell-like structure 131 along its longitudinal axis towards the light beam 141 of the optical sensing arrangement 140 as the apex portion 134 collapses relative to the peripheral base portion 132 may move the plunger-like element 136 of the elastic deformable shell-like structure 131 perpendicularly with respect to the light beam 141 of the optical sensing arrangement 140 to cause the plunger-like element 136 to interrupt the light beam 141 of the optical sensing arrangement 140 in a perpendicular manner with the free-end 136a of the plunger-like element 136 blocking or obstructing the light beam 141.

According to various embodiments, since the free-end 136a of the plunger-like element 136 is opaque, interrupting the light beam 141 of the optical sensing arrangement 140 may block the light beam 141 such that the light beam 141 fails to reach the light sensing module of the optical sensing arrangement 140. Accordingly, a break or disruption to the light sensing module of the optical sensing arrangement 140 receiving the light beam 141 may be treated as a measure of the actuation or depression of the keycap 110.

According to various embodiments, the substrate 120 may include a first surface 122 and a second surface 124. The first surface 122 and the second surface 124 may be opposite surfaces of the substrate 120. Accordingly, the first surface 122 and the second surface 124 may be opposite each other. Further, the first surface 122 and the second surface 124 may be the two opposite broad surfaces of the substrate 120. According to various embodiments, the substrate 120 may include a through-hole 126 extending between the first surface 122 and the second surface 124. According to various embodiments, the peripheral base portion 132 of the elastic deformable shell-like structure 131 may be in abutment with the first surface 122 of the substrate 120. Accordingly, the clastic deformable shell-like structure 131 may be on the first surface 122 of the substrate 120 with the elastic deformable shell-like structure 131 abutting the first surface 122 of the substrate 120. According to various embodiments, the plunger-like element 136 of the elastic deformable shell-like structure 131 may be aligned with the through-hole 126 such that the free-end 136a of the plunger-like element 136 may be retractably insertable through the through-hole 126 along the longitudinal axis 136b of the plunger-like element 136 when the keycap 110 is being actuated or depressed. According to various embodiments, the longitudinal axis 136b of the plunger-like element 136 of the elastic deformable shell-like structure 131 may be aligned with the through-hole 126 of the substrate 120. According to various embodiments, the longitudinal axis 136b of the plunger-like element 136 of the elastic deformable shell-like structure 131 may be aligned with a centreline (or hole-axis) of the through-hole 126 of the substrate 120. According to various embodiments, since the clastic deformable shell-like structure 131 is elastically deformed to collapse the apex portion 134 relative to the peripheral base portion 132 to move the plunger-like element 136 along its longitudinal axis 136b for inserting the free-end 136a of the plunger-like element 136 through the through-hole 126 of the substrate 120, the free-end 136a of the plunger-like element 136 may be retracted from the through-hole 126 of the substrate 120 as the elastic deformable shell-like structure 131 returns to its original state when the actuation or depression force is removed.

According to various embodiments, the first component 142 of the optical sensing arrangement 140 and the second component 144 of the optical sensing arrangement 140 may be on opposite sides of the through-hole 126 of the substrate 120. According to various embodiments, the first component 142 of the optical sensing arrangement 140 and the second component 144 of the optical sensing arrangement 140 may be mounted or attached or coupled or bonded to the substrate 120 at two opposite sides of the through-hole 126 of the substrate 120. Accordingly, when the free-end 136a of the plunger-like element 136 of the elastic deformable shell-like structure 131 is retractably inserted through the through-hole 126 of the substrate 120, the free-end 136a of the plunger-like element 136 of the elastic deformable shell-like structure 131 may interrupt the light beam 141 of the optical sensing arrangement 140 that is transmitted across the through-hole 126 of the substrate 120 between the first component 142 of the optical sensing arrangement 140 and the second component 144 of the optical sensing arrangement 140.

According to various embodiments, the optical sensing arrangement 140 may be disposed on the second surface 124 of the substrate 120. Accordingly, the optical sensing arrangement 140 may be mounted or attached or coupled or bonded to the second surface 124 of the substrate 120. Hence, the first component 142 of the optical sensing arrangement 140 and the second component 144 of the optical sensing arrangement 140 may be mounted or attached or coupled or bonded to the second surface 124 of the substrate 120. According to various embodiments, the optical sensing arrangement 140 may be disposed in a manner so as to transmit the light beam 141 in a direction parallel to the second surface 124 of the substrate 120 and across the through-hole 126 of the substrate 120. Accordingly, the the first component 142 of the optical sensing arrangement 140 and the second component 144 of the optical sensing arrangement 140 may be disposed on the second surface 124 of the substrate 120 and arranged with respect to the through-hole 126 of the substrate 120 such that the light beam 141 may be projected across the through-hole 126 of the substrate 120 in a manner parallel to the second surface 124 of the substrate 120. According to various embodiments, the first component 142 of the optical sensing arrangement 140 and the second component 144 of the optical sensing arrangement 140 may be mounted or attached or coupled or bonded to the second surface 124 of the substrate 120 at two opposite sides of the through-hole 126 of the substrate 120. Accordingly, when the free-end 136a of the plunger-like element 136 of the elastic deformable shell-like structure 131 is retractably inserted through the through-hole 126 of the substrate 120, the free-end 136a of the plunger-like element 136 of the elastic deformable shell-like structure 131 may interrupt the light beam 141 of the optical sensing arrangement 140 that is transmitted across the through-hole 126 of the substrate 120 between the first component 142 of the optical sensing arrangement 140 and the second component 144 of the optical sensing arrangement 140 on the second surface 124 of the substrate 120.

According to various embodiments, the elastic deformable shell-like structure 131 may be transparent or translucent except for the free-end 136a of the plunger-like element 136 of the elastic deformable shell-like structure 131, which is opaque. Accordingly, only the free-end 136a of the plunger-like element 136 of the elastic deformable shell-like structure 131 may be opaque while the remaining portions of the elastic deformable shell-like structure 131 may be transparent or translucent. Hence, the peripheral base portion 132 and the apex portion 134 of the elastic deformable shell-like structure may be transparent or translucent.

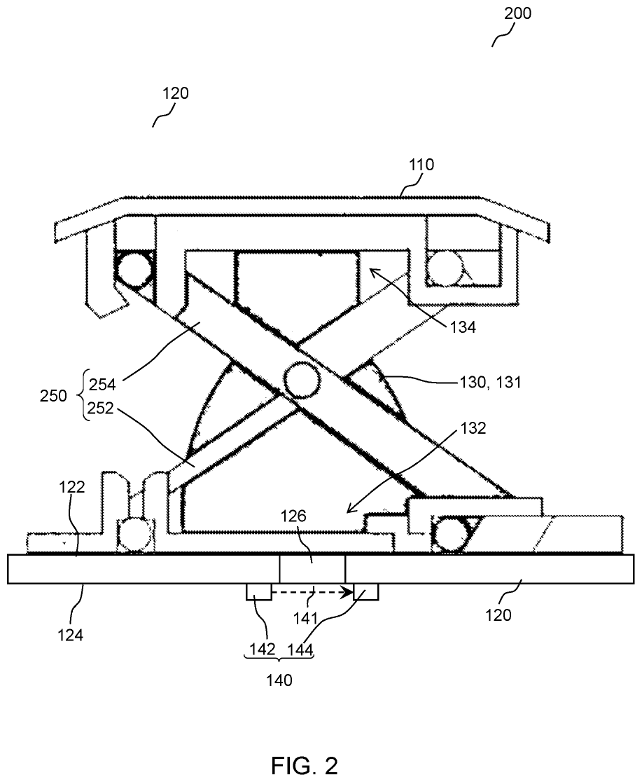

FIG. 2 shows a side view of an input key assembly 200 according to various embodiments. According to various embodiments, the input key assembly 200 of FIG. 2 includes all the features of the input key assembly 100 of FIG. 1A and FIG. 1B. Accordingly, all features, changes, modifications, and variations that are applicable to the input key assembly 100 of FIG. 1A and FIG. 1B may also be applicable to the input key assembly 200 of FIG. 2.

According to various embodiments, the input key assembly 200 of FIG. 2 may, similar to the input key assembly 100 of FIG. 1A and FIG. 1B, include the keycap 110, the substrate, the collapsible component 130 in the form of the elastic deformable shell-like structure 131, and the optical sensing arrangement 140 as previously described in relation to the input key assembly 100 of FIG. 1A and FIG. 1B.

According to various embodiments, the input key assembly 200 of FIG. 2 may further include a scissor mechanism 250. According to various embodiments, the scissor mechanism 250 may guide a relative movement between the keycap 110 and the substrate 120 when the keycap 110 is being actuated or depressed. According to various embodiments, the relative movement between the keycap 110 and the substrate 120 may be directly perpendicular to the keycap 110 and the substrate 120. Accordingly, the scissor mechanism 250 may guide the keycap 110 to move perpendicularly towards and/or away from the substrate 120. According to various embodiments, the scissor mechanism 250 may move the keycap 110 with respect to the substrate 120 via a scissor motion. According to various embodiments, the scissor mechanism 250 may guide the keycap 110 to move perpendicularly or vertically with respect to the substrate 120. According to various embodiments, a direction of the relative movement between the keycap 110 and the substrate 120 guided by the scissor mechanism 250 may be aligned with the movement of the plunger-like element 136 of the elastic deformable shell-like structure 131 as the keycap 110 is being actuated or depressed. According to various embodiments, the direction of the relative movement between the keycap 110 and the substrate 120 guided by the scissor mechanism 250 may be parallel to the longitudinal axis 136b of the plunger-like element 136 of the elastic deformable shell-like structure 131. Accordingly, the scissor mechanism 250 may guide the keycap 110 to move relative to the substrate 120 in the direction parallel to the longitudinal axis 136b of the plunger-like element 136 of the elastic deformable shell-like structure 131 such that the keycap 110 may collapse the elastic deformable shell-like structure 131 to move the plunger-like element 136 of the elastic deformable shell-like structure 131 along its longitudinal axis 136b.

According to various embodiments, the scissor mechanism 250 may include at least one set of link members 252, 254 arranged in a criss-cross arrangement and pivotable about a centre of the criss-cross arrangement. According to various embodiments, the scissor mechanism 250 may include two sets of link member 252, 254 on opposite sides of the elastic deformable shell-like structure 131 so as to provide synchronised scissor motion for guiding the relative movement between the keycap 110 and the substrate 120 when the keycap 110 is being actuated or depressed.

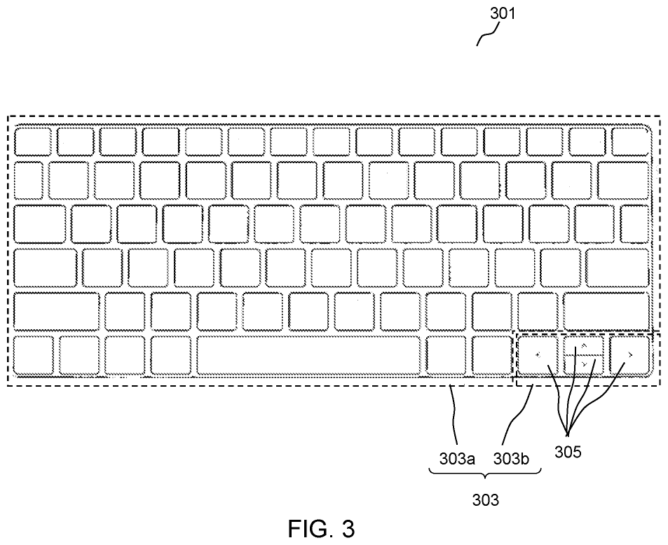

FIG. 3 shows an input device 301 according to various embodiments. According to various embodiments, the input device 301 may include a keyboard or a keypad. According to various embodiments, the input device 301 may include a plurality of input keys 303. According to various embodiments, at least one of the plurality of input keys 303 may include the input key assembly 100, 200 of the various embodiments. According to various embodiments, the at least one of the plurality of input keys 303 may be of a size smaller than the standard base size of 1 u. For example, the at least one of the plurality of input keys 303 may be 0.5 u in size. According to various embodiments, the input device 301 may include a first set of input keys 303a using conventional key switch technology, such as conventional optical switch, conventional mechanical switch, conventional dome-switch, conventional scissor switch, etc., and a second set of input keys 303b using the input key assembly of the various embodiments. According to various embodiments, at least one input key of the second set of input keys 303b may be of a size smaller than the standard base size of 1 u. For example, the at least one input key of the second set of input keys 303b may be 0.5 u in size. As another example, two of the second set of input keys 303b may be 0.5 u in size.

According to various embodiments, the arrow keys 305 of the input device 301 may be configured to operate according to the input key assembly 100, 200 of the various embodiments. Accordingly, each of the arrow key 305 of the input device 301 may include the input key assembly 100, 200 of the various embodiments. According to various embodiments, two of the arrow keys 305 may be 0.5 u in size and two of the arrow keys 305 may be 1 u in size. According to various embodiments, for example, the up and down arrow keys 305 may be 0.5 u in size and the left and right arrow keys 305 may be 1 u in size.

Various embodiments have provided improved input key assembly which may operate in a manner similar to the optical switch technology but for a key smaller than the standard base size of 1 u, which is not achievable with conventional optical key switch. Various embodiments have provided an input device including one or more keys configured based on the improved input key assembly of the various embodiments. Accordingly, various embodiments have enabled optical switching technology to be implemented for keys smaller than the standard base size of 1 u in an input device, such as a keyboard or a keypad.

While the invention has been particularly shown and described with reference to specific embodiments, it should be understood by those skilled in the art that various changes, modification, variation in form and detail may be made therein without departing from the scope of the invention as defined by the appended claims. The scope of the invention is thus indicated by the appended claims and all changes which come within the meaning and range of equivalency of the claims are therefore intended to be embraced.

What is claimed is:

1. An input key assembly comprising:
a keycap;
a substrate;
an elastic deformable shell-like structure disposed between the substrate and the keycap, wherein the elastic deformable shell-like structure comprises:
a peripheral base portion in abutment with the substrate,
an apex portion in abutment with the keycap, wherein the peripheral base portion tapers towards the apex portion, and
a plunger-like element extending from underneath the apex portion and away from the apex portion, wherein a free-end of the plunger-like element is opaque; and
an optical sensing arrangement disposed on the substrate to transmit a light beam and sense an interruption to the light beam,
wherein the elastic deformable shell-like structure and the optical sensing arrangement are arranged in a manner so as to interrupt the light beam with the free-end of the plunger-like element when the keycap is depressed to deform the elastic deformable shell-like structure for collapsing the apex portion relative to the peripheral base portion to move the plunger-like element along a longitudinal axis of the plunger-like element.

2. The input key assembly as claimed in claim 1,
wherein the substrate comprises:
a first surface,
a second surface, wherein the first surface and the second surface are opposite surfaces of the substrate, and
a through-hole extending between the first surface and the second surface,
wherein the peripheral base portion of the elastic deformable shell-like structure is in abutment with the first surface of the substrate and the plunger-like element of the elastic deformable shell-like structure is aligned with the through-hole such that the free-end of the plunger-like element is retractably insertable through the through-hole along the longitudinal axis of the plunger-like element when the keycap is depressed.

3. The input key assembly as claimed in claim 2,
wherein the optical sensing arrangement is disposed on the second surface of the substrate in a manner so as to transmit the light beam in a direction parallel to the second surface and across the through-hole.

4. The input key assembly as claimed in claim 1, wherein the optical sensing arrangement comprises a transmitter and a receiver, or a transceiver and a reflector.

5. The input key assembly as claimed in claim 1, further comprising a scissor mechanism to guide a relative movement between the keycap and the substrate in a direction parallel to the longitudinal axis of the plunger-like element.

6. The input key assembly as claimed in claim 1, wherein the elastic deformable shell-like structure comprises an inverted-bowl-like shape, a dome-like shape, a cone-like shape, a frustoconical-like shape, or a bell-like shape.

7. The input key assembly as claimed in claim 1, wherein the peripheral base portion and the apex portion of the elastic deformable shell-like structure are transparent or translucent.

8. An input device comprising:
a plurality of input keys,
wherein at least one of the input keys comprises:
an input key assembly comprising
a keycap,
a substrate,
an elastic deformable shell-like structure disposed between the substrate and the keycap, wherein the elastic deformable shell-like structure comprises
a peripheral base portion in abutment with the substrate,
an apex portion in abutment with the keycap, wherein the peripheral base portion tapers towards the apex portion, and
a plunger-like element extending from underneath the apex portion and away from the apex portion, wherein a free-end of the plunger-like element is opaque, and
an optical sensing arrangement disposed on the substrate to transmit a light beam and sense an interruption to the light beam,
wherein the elastic deformable shell-like structure and the optical sensing arrangement are arranged in a manner so as to interrupt the light beam with the free-end of the plunger-like element when the keycap is depressed to deform the elastic deformable shell-like structure for collapsing the apex portion relative to the peripheral base portion to move the plunger-like element along a longitudinal axis of the plunger-like element.

9. The input device as claimed in claim 8,
wherein the substrate of the input key assembly comprises:
a first surface,
a second surface, wherein the first surface and the second surface are opposite surfaces of the substrate, and
a through-hole extending between the first surface and the second surface,
wherein the peripheral base portion of the elastic deformable shell-like structure is in abutment with the first surface of the substrate and the plunger-like element of the elastic deformable shell-like structure is aligned with the through-hole such that the free-end of the plunger-like element is retractably insertable through the through-hole along the longitudinal axis of the plunger-like element when the keycap is depressed.

10. The input device as claimed in claim 9,
wherein the optical sensing arrangement of the input key assembly is disposed on the second surface of the substrate in a manner so as to transmit the light beam in a direction parallel to the second surface and across the through-hole.

11. The input device as claimed in claim 8, wherein the optical sensing arrangement of the input key assembly comprises a transmitter and a receiver, or a transceiver and a reflector.

12. The input device as claimed in claim 8, wherein the input key assembly further comprises a scissor mechanism to guide the relative movement between the keycap and the substrate in a direction parallel to the longitudinal axis of the plunger-like element.

13. The input device as claimed in claim 8, wherein the elastic deformable shell-like structure of the input key assembly comprises an inverted-bowl-like shape, a dome-like shape, a cone-like shape, a frustoconical-like shape, or a bell-like shape.

14. The input device as claimed in claim 8, wherein the peripheral base portion and the apex portion of the elastic deformable shell-like structure of the input key assembly are transparent or translucent.

15. The input device as claimed in claim 8,
wherein the plurality of keys comprises arrow keys,
wherein at least one of the arrow keys comprises the input key assembly.
